(19) United States
(12) Patent Application Publication
(10) Pub. No.: US 2025/0301896 A1
(43) Pub. Date: Sep. 25, 2025

(54) DISPLAY DEVICE

(71) Applicant: Japan Display Inc., Tokyo (JP)

(72) Inventors: Hiroshi TABATAKE, Tokyo (JP); Tetsuo MORITA, Tokyo (JP); Kenji HARADA, Tokyo (JP)

(73) Assignee: Japan Display Inc., Tokyo (JP)

(21) Appl. No.: 19/088,817

(22) Filed: Mar. 24, 2025

(30) Foreign Application Priority Data
Mar. 25, 2024 (JP) 2024-048066

(51) Int. Cl. H10K 59/88; H10K 59/121; H10K 59/131

(52) U.S. Cl. CPC H10K 59/88; H10K 59/1213; H10K 59/131

(57) ABSTRACT

According to one embodiment, a display device includes a line which supplies a signal or voltage, subpixels each of which includes a display element including an organic layer and a pixel circuit, and a dummy subpixel which includes the display element and a dummy pixel circuit. The pixel circuits and the dummy pixel circuit constitute a circuit line arranged along the line. The dummy pixel circuit is located at an end of the circuit line. In each of the subpixels, an electric path which reaches the display element from the line through the pixel circuit is formed. In the dummy subpixel, at least part of an electric path which reaches the display element from the line through the dummy pixel circuit is cut.

### CROSS-REFERENCE TO RELATED APPLICATION

This application is based upon and claims the benefit of priority from Japanese Patent Application No. 2024-048066, filed Mar. 25, 2024, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In this type of display devices, a technique which can improve the yield and reliability is required.

### BRIEF DESCRIPTION OF THE DRAWINGS

FIG. 1 is a diagram showing a configuration example of a display device according to an embodiment.

FIG. 2 is a circuit diagram showing an example of a configuration which can be applied to a pixel circuit.

FIG. 3 is a schematic plan view showing an example of the layout form of three pixel circuits provided for one pixel.

FIG. 4 is a schematic plan view showing an example of the layout of the display elements of three subpixels provided in a pixel.

FIG. 5 is the schematic cross-sectional view of the display device along the V-V line of FIG. 4.

FIG. 6 is a schematic plan view showing the vicinity of the boundary between a display area and a surrounding area.

FIG. 7 is a schematic plan view showing a configuration which can be applied to dummy pixels.

FIG. 8 is a schematic plan view showing an example of the layout form of three dummy pixel circuits provided for a dummy pixel.

FIG. 9 is a circuit diagram showing an example of a configuration which can be applied to the dummy pixel circuits.

FIG. 10 is a schematic plan view showing an example of a configuration which can be applied to the pixel circuits and dummy pixel circuits provided near the boundary between the display area and the surrounding area.

FIG. 11 is an enlarged plan view of the pixel circuit shown in FIG. 10.

FIG. 12 is an enlarged plan view of the dummy pixel circuit shown in FIG. 10.

### DETAILED DESCRIPTION

In general, according to one embodiment, a display device comprises a line which supplies a signal or voltage, a plurality of subpixels each of which includes a display element including an organic layer which emits light based on application of voltage, and a pixel circuit which drives the display element, and a dummy subpixel which includes the display element and a dummy pixel circuit. The pixel circuits of the subpixels and the dummy pixel circuit constitute a circuit line arranged along the line. The dummy pixel circuit is located at an end of the circuit line. In each of the subpixels, an electric path which reaches the display element from the line through the pixel circuit is formed. In the dummy subpixel, at least part of an electric path which reaches the display element from the line through the dummy pixel circuit is cut.

This configuration can realize the improvement of the yield of a display device or the improvement of reliability.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

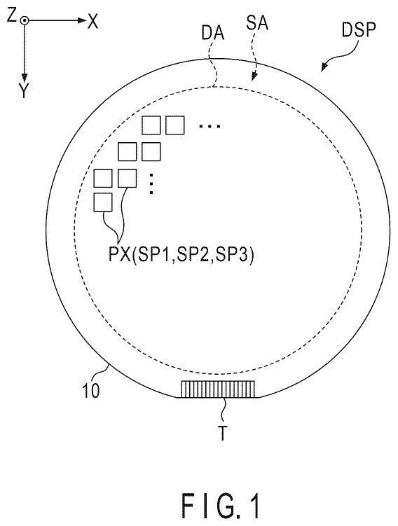

FIG. 1 is a diagram showing a configuration example of a display device DSP according to an embodiment. The display device DSP comprises an insulating substrate 10. The substrate 10 has a display area DA which displays an image, and a surrounding area SA located around the display area DA. The substrate 10 may be glass or a resinous film having flexibility.

In the embodiment, the substrate 10 and the display area DA are circles (precise circles) as seen in plan view. It should be noted that the shape of each of the substrate 10 and the display area DA in plan view is not limited to this example and may be another shape such as a rectangle, a square or an oval.

The display area DA comprises a plurality of pixels PX arrayed in matrix in an X-direction and a Y-direction. Each pixel includes a plurality of subpixels SP which display different colors. This embodiment assumes a case where each pixel PX includes a green subpixel SP1, a red subpixel SP2 and a blue subpixel SP3. However, each pixel PX may include a subpixel SP which exhibits another color such as white in addition to subpixels SP1, SP2 and SP3 or instead of one of subpixels SP1, SP2 and SP3.

The display device DSP further comprises a terminal portion T provided in the surrounding area SA. For example, a flexible printed circuit which applies voltage and signals for driving the display device DSP is connected to the terminal portion T.

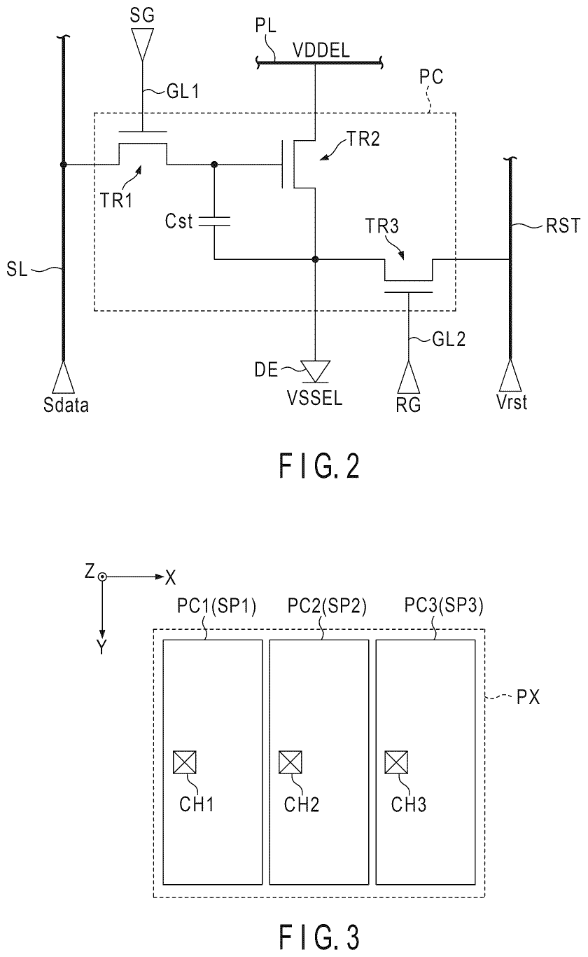

FIG. 2 is a circuit diagram showing an example of a configuration which can be applied to a pixel circuit PC provided in each subpixel SP (SP1, SP2 or SP3). The pixel circuit PC shown in the figure includes three thin-film transistors TR1, TR2 and TR3 and a storage capacitor Cst. Further, the display device DSP comprises, as examples of lines which supply signals or voltage to the pixel circuit PC, a signal line SL, a power line PL, a reset line RST, a scanning line GL1 and a scanning line GL2.

In the following explanation, one of the source and drain electrodes of each of the thin-film transistors TR1, TR2 and TR3 is referred to as a first electrode, and the other one is referred to as a second electrode. Similarly, one electrode of the storage capacitor Cst is referred to as a first electrode, and the other electrode is referred to as a second electrode.

The gate electrode of the thin-film transistor TR1 is connected to the scanning line GL1 which supplies scanning signals SG. The gate electrode of the thin-film transistor TR2 is connected to the scanning line GL2 which supplies reset signals RG.

The first electrode of the thin-film transistor TR1 is connected to the signal line SL which supplies video signals Sdata. Video signals Sdata are signals which are written to subpixels SP for image display. The first electrode of the thin-film transistor TR2 is connected to the power line PL which applies drive voltage VDDEL. The first electrode of the thin-film transistor TR3 is connected to the reset line RST which applies reset voltage Vrst.

The second electrode of the thin-film transistor TR1 is connected to the gate electrode of the thin-film transistor TR2 and the first electrode of the storage capacitor Cst. The second electrode of the thin-film transistor TR2 is connected to the anode of the display element DE included in the subpixel SP and the second electrode of the storage capacitor Cst. Similarly, the second electrode of the thin-film transistor TR3 is connected to the anode of the display element DE and the second electrode of the storage capacitor Cst. Voltage VSSEL is applied to the cathode of the display element DE.

It should be noted that the configuration of the pixel circuit PC is not limited to the example shown in FIG. 2. For example, the pixel circuit PC may comprise four or more transistors. Further, the pixel circuit PC may comprise a plurality of storage capacitors Cst.

FIG. 3 is a schematic plan view showing an example of the layout form of the pixel circuits PC provided for one pixel PX. In the example of FIG. 3, the pixel circuits PC (PC1, PC2 and PC3) of subpixels SP1, SP2 and SP3 are arranged in the X-direction.

The pixel circuits PC1, PC2 and PC3 are connected to the display elements DE of subpixels SP1, SP2 and SP3 via contact holes CH1, CH2 and CH3 provided in an organic insulating layer 12 as described later, respectively. In the example of FIG. 3, the contact holes CH1, CH2 and CH3 are arranged in the X-direction. It should be noted that the layout form of the contact holes CH1, CH2 and CH3 is not limited to this example.

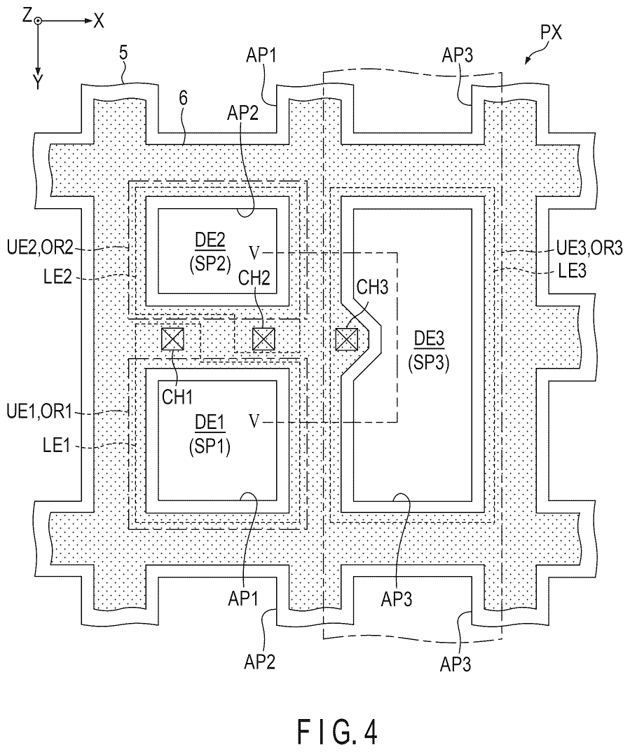

FIG. 4 is a schematic plan view showing an example of the layout of the display elements DE (DE1, DE2 and DE3) of subpixels SP1, SP2 and SP3. In the example of FIG. 4, each of the display elements DE1 and DE2 is adjacent to the display element DE3 in the X-direction. Further, the display elements DE1 and DE2 are arranged in the Y-direction.

When the display elements DE1, DE2 and DE3 are provided in line with this layout, a column in which the display elements DE1 and DE2 are alternately provided in the Y-direction and a column in which a plurality of display elements DE3 are repeatedly provided in the Y-direction are formed in the display area DA. These columns are alternately arranged in the X-direction. It should be noted that the layout of the display elements DE1, DE2 and DE3 is not limited to the example of FIG. 4.

A rib layer 5 is provided in the display area DA. The rib layer 5 has a pixel aperture AP1 which surrounds the display element DE1, a pixel aperture AP2 which surrounds the display element DE2 and a pixel aperture AP3 which surrounds the display element DE3.

In the example of FIG. 4, the pixel aperture AP2 is smaller than the pixel aperture AP1. The pixel aperture AP3 is larger than the pixel aperture AP1. Thus, among subpixels SP1, SP2 and SP3, the aperture ratio of subpixel SP3 is the greatest, and the aperture ratio of subpixel SP2 is the least. However, the relationship of the aperture ratios of subpixels SP1, SP2 and SP3 is not limited to this example.

The display element DE1 comprises a lower electrode LE1, an upper electrode UE1 and an organic layer OR1 overlapping the pixel aperture AP1. The display element DE2 comprises a lower electrode LE2, an upper electrode UE2 and an organic layer OR2 overlapping the pixel aperture AP2. The display element DE3 comprises a lower electrode LE3, an upper electrode UE3 and an organic layer OR3 overlapping the pixel aperture AP3.

A partition 6 having a grating shape is provided on the rib layer 5. The partition 6 overlaps the rib layer 5 as a whole and has a planar shape similar to that of the rib layer 5. In other words, the partition 6 has apertures which surround the display elements DE1, DE2 and DE3. The partition 6 functions as lines which apply cathode voltage to the upper electrodes UE1, UE2 and UE3. Each of the contact holes CH1, CH2 and CH3 described above overlaps the rib layer 5 and the partition 6.

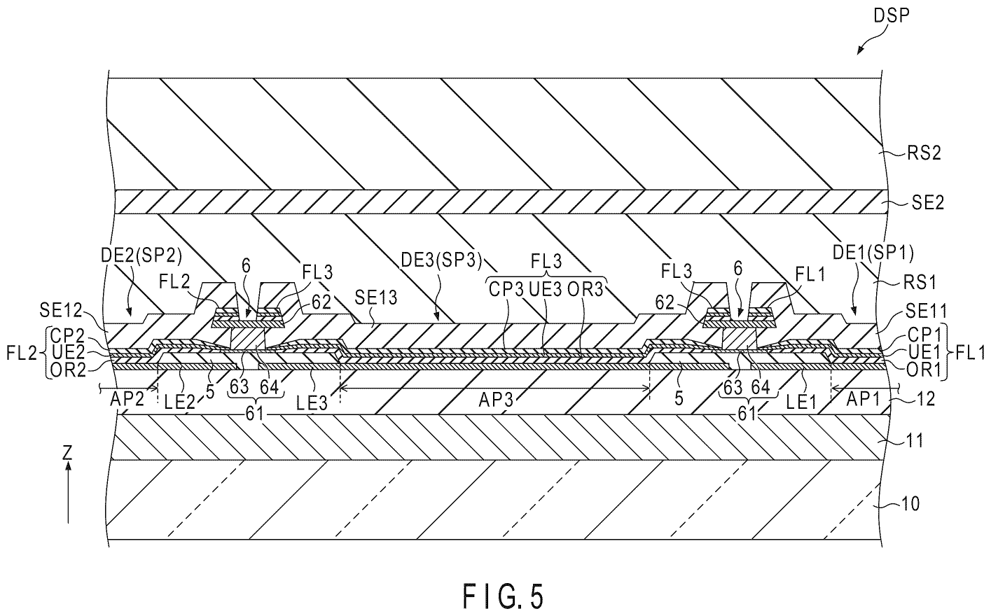

FIG. 5 is the schematic cross-sectional view of the display device DSP along the V-V line of FIG. 4. A circuit layer 11 is provided on the substrate 10 described above. The circuit layer 11 includes various circuits and lines such as the pixel circuits PC (PC1, PC2 and CP3), signal lines SL, reset lines RST, power lines PL and scanning lines GL1 and GL2 shown in FIG. 2. The circuit layer 11 is covered with the organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. The lower electrodes LE1, LE2 and LE3 are connected to the pixel circuits PC1, PC2 and PC3 of the circuit layer 11 through the contact holes CH1, CH2 and CH3 (see FIG. 3 and FIG. 4) provided in the organic insulating layer 12, respectively.

The partition 6 includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 5, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 5, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3.

The upper electrodes UE1, UE2 and UE3 are in contact with the lower portions 61 of the partition 6. Specifically, each of the upper electrodes UE1, UE2 and UE3 covers the bottom layer 63 protruding from the side surface of the stem layer 64. Each of the upper electrodes UE1, UE2 and UE3 may further cover at least part of the side surface of the stem layer 64.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located around the partition 6 (in other words, the portion which constitutes the display element DE1). Similarly, the stacked film FL2 is partly located on the upper portion 62. This portion is spaced apart from, of the stacked film FL2, the portion located around the partition 6 (in other words, the portion which constitutes the display element DE2). Further, the stacked film FL3 is partly located on the upper portion 62. This portion is spaced apart from, of the stacked film FL3, the portion located around the partition 6 (in other words, the portion which constitutes the display element DE3). It should be noted that at least one of the stacked films FL1, FL2 and FL3 may not be provided on the partition 6.

Sealing layers SE11, SE12 and SE13 are provided in subpixels SP1, SP2 and SP3, respectively. The sealing layer SE11 continuously covers the cap layer CP1 and the partition 6 around subpixel SP1. The sealing layer SE12 continuously covers the cap layer CP2 and the partition 6 around subpixel SP2. The sealing layer SE13 continuously covers the cap layer CP3 and the partition 6 around subpixel SP3.

In the example of FIG. 5, the stacked film FL1 and sealing layer SE11 located on the partition 6 between the display elements DE1 and DE3 are spaced apart from the stacked film FL3 and sealing layer SE13 located on this partition 6. The stacked film FL2 and sealing layer SE12 located on the partition 6 between the display elements DE2 and DE3 are spaced apart from the stacked film FL3 and sealing layer SE13 located on this partition 6.

The sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). In this embodiment, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6 is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

For example, the upper portion 62 of the partition 6 comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy can be used. For the conductive oxide forming the upper layer, for example, ITO or IZO can be used. It should be noted that the upper portion 62 may comprise a single-layer structure of a metal material. The upper portion 62 may further include a layer formed of an insulating material.

Cathode voltage is applied to the partition 6. This cathode voltage is applied to each of the upper electrodes UE1, UE2 and UE3 which are in contact with the lower portions 61. Voltage is applied to the lower electrodes LE1, LE2 and LE3 through the pixel circuits PC (PC1, PC2 and PC3) provided in subpixels SP1, SP2 and SP3, respectively, based on the video signals Sdata of the signal lines SL.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a green wavelength range. When a potential difference is formed between the lower electrode LE2 and the upper electrode UE2, the light emitting layer of the organic layer OR2 emits light in a red wavelength range. When a potential difference is formed between the lower electrode LE3 and the upper electrode UE3, the light emitting layer of the organic layer OR3 emits light in a blue wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

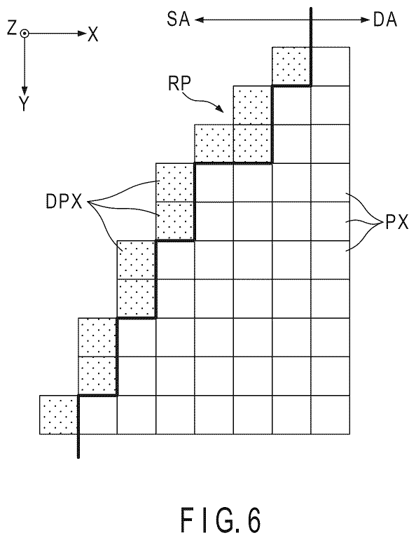

FIG. 6 is a schematic plan view showing the vicinity of the boundary between the display area DA and the surrounding area SA. In this embodiment, the outer shape of the display area DA has a curved round portion RP. Specifically, when the display area DA is circular as shown in FIG. 1, the whole outer shape corresponds to the round portion RP. As another example, the outer shape of the display area DA may include the round portion RP and a linear portion.

In the display area DA, a plurality of pixels PX are provided as described above. In the round portion RP, for example, pixels PX are provided in a staircase pattern as shown in FIG. 6.

In the surrounding area SA, a plurality of dummy pixels DPX which do not display image (do not light up) are provided. The dummy pixels DPX are adjacent to the pixels PX provided in the outermost circumference of the display area DA in the X-direction or the Y-direction. For example, the dummy pixels DPX are provided so as to surround the display area DA. In this case, all of the pixels PX provided in the outermost circumference of the display area DA are adjacent to the dummy pixels DPX. It should be noted that at least one of the pixels PX provided in the outermost circumference of the display area DA may not be adjacent to the dummy pixels DPX.

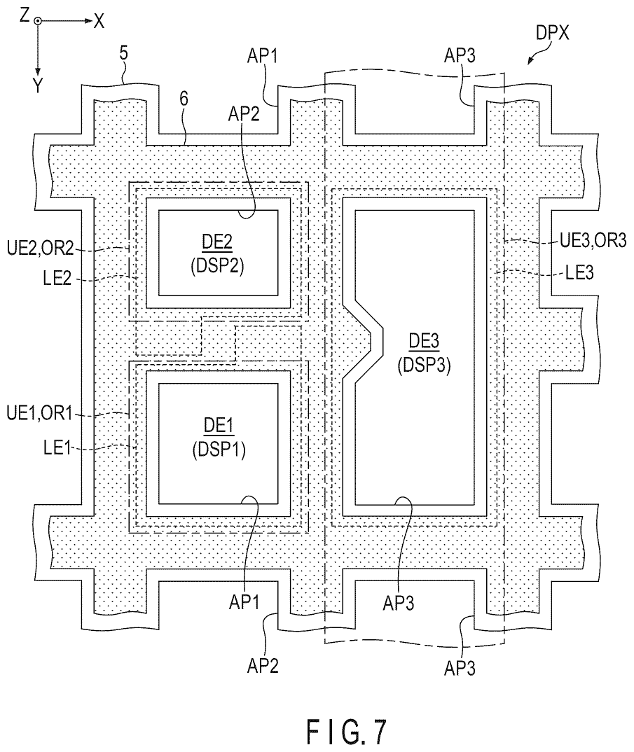

FIG. 7 is a schematic plan view showing a configuration which can be applied to dummy pixels DPX. The dummy pixel DPX comprises dummy subpixels DSP1, DSP2 and DSP3. Dummy subpixel DSP1 comprises a display element DE1 in a manner similar to that of subpixel SP1. Dummy subpixel DSP2 comprises a display element DE2 in a manner similar to that of subpixel SP2. Dummy subpixel DSP3 comprises a display element DE3 in a manner similar to that of subpixel SP3.

The layout of the display elements DE1, DE2 and DE3 of the dummy pixel DPX is similar to, for example, that of the display elements DE1, DE2 and DE3 of the pixel PX shown in FIG. 4. In the example of FIG. 7, pixel apertures AP1, AP2 and AP3 which overlap the display elements DE1, DE2 and DE3 of the dummy pixel DPX are provided in the rib layer 5. Further, each of the display elements DE1, DE2 and DE3 of the dummy pixel DPX is surrounded by the partition 6.

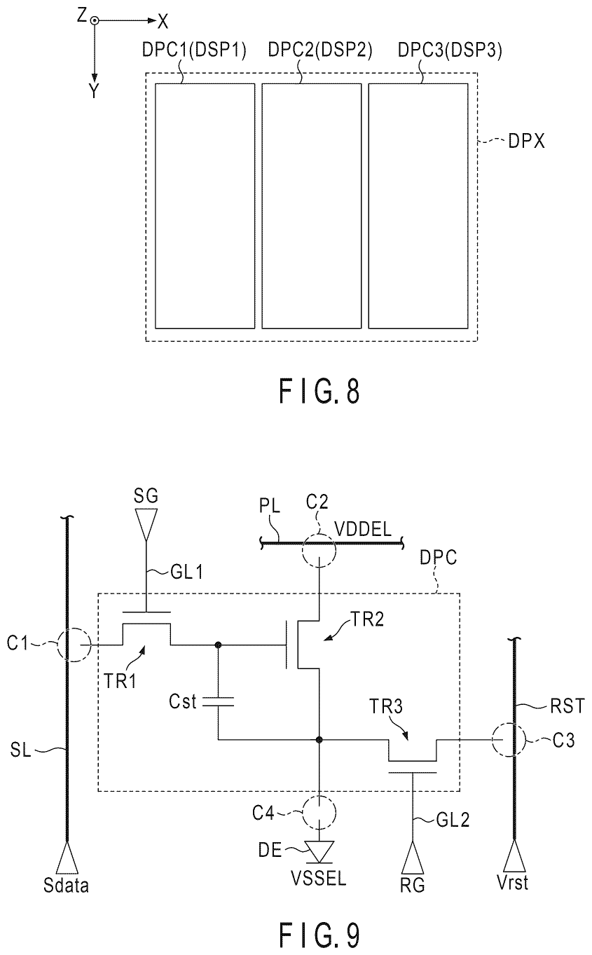

FIG. 8 is a schematic plan view showing an example of the layout form of dummy pixel circuits DPC provided for a dummy pixel DPX. The dummy subpixels DSP1, DSP2 and DSP3 comprise dummy pixel circuits DPC (DPC1, DPC2 and DPC3), respectively. The dummy pixel circuits DPC1, DPC2 and DPC3 are arranged in the X-direction in a manner similar to that of the pixel circuits PC1, PC2 and PC3 shown in FIG. 3.

In the examples of FIG. 7 and FIG. 8, the contact hole CH1, CH2 or CH3 shown in FIG. 4 is not provided. In this case, the display element DE1, DE2 or DE3 of the dummy pixel DPX is not connected to the dummy pixel circuit DPC1, DPC2 or DPC3. As another example, the contact holes CH1, CH2 and CH3 may be provided in the dummy pixel DPX, and the display elements DE1, DE2 and DE3 may be connected to the dummy pixel circuits DPC1, DPC2 and DPC3 through these contact holes.

FIG. 9 is a circuit diagram showing an example of a configuration which can be applied to the dummy pixel circuits DPC (DPC1, DPC2 and DPC3). The dummy pixel circuit DPC includes thin-film transistors TR1, TR2 and TR3 and a storage capacitor Cst in a manner similar to that of the pixel circuit PC shown in FIG. 2.

In each of subpixels SP1, SP2 and SP3, an electric path which reaches the display element DE through the pixel circuit PC from the lines (the signal line SL, power line PL and reset line RST) which supply signals or voltage related to the driving of the display element DE is formed. However, in each dummy subpixel DSP, at least part of the electric path is cut. By this configuration, the display element DE of the dummy subpixel DSP does not light up.

Specifically, in the example of FIG. 9, cut portions C1, C2, C3 and C4 shown by chained circles are provided. In the cut portion C1, the electric path between the dummy pixel circuit DPC and the signal line SL, specifically, the path between the thin-film transistor TR1 and the signal lie SL, is cut. In the cut portion C2, the electric path between the dummy pixel circuit DPC and the power line PL, specifically, the path between the thin-film transistor TR2 and the power line PL, is cut. In the cut portion C3, the electric path between the dummy pixel circuit DPC and the reset line RST, specifically, the path between the thin-film transistor TR3 and the reset line RST, is cut. In the cut portion C4, the path between the dummy pixel circuit DPC and the display element DE, specifically, the path between the thin-film transistors TR2 and TR3 and the display element DE, is cut.

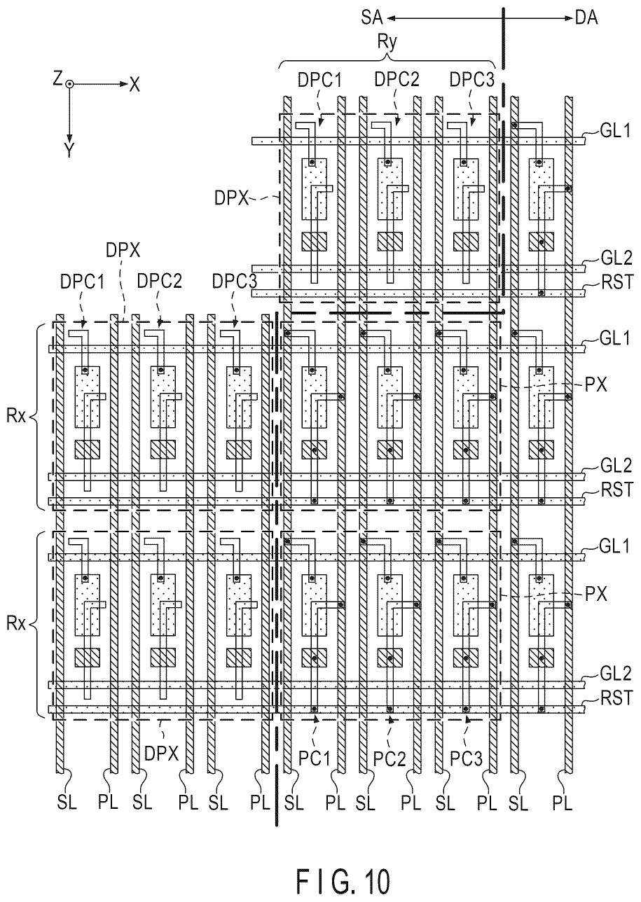

FIG. 10 is a schematic plan view showing an example of a configuration which can be applied to the pixel circuits PC and dummy pixel circuits DPC provided near the boundary between the display area DA and the surrounding area SA. In the example of this figure, one dummy pixel DPX is provided on the external side of each pixel PX provided in the outermost circumference of the display area DA.

The signal lines SL and the power lines PL extend in the Y-direction. The scanning lines GL1 and GL2 and the reset lines RST extend in the X-direction. The signal lines SL and the power lines PL consist of, for example, a first metal layer included in the circuit layer 11 shown in FIG. 5. The scanning lines GL1 and GL2 and the reset lines RST consist of, for example, a second metal layer included in the circuit layer 11.

The pixel circuits PC1, PC2 and PC3 and dummy pixel circuits DPC1, DPC2 and DPC3 arranged in the X-direction constitute a circuit line Rx. The pixel circuits PC1, PC2 and PC3 and dummy pixel circuits DPC1, DPC2 and DPC3 arranged in the Y-direction constitute a circuit line Ry.

The scanning lines GL1 and GL2 and the reset line RST extend over the pixel circuits PC1, PC2 and PC3 and dummy pixel circuits DPC1, DPC2 and DPC3 constituting each circuit line Rx. From another viewpoint, the pixel circuits PC1, PC2 and PC3 and dummy pixel circuits DPC1, DPC2 and DPC3 constituting each circuit line Rx are arranged along a corresponding scanning line GL1, a corresponding scanning line GL2 and a corresponding reset line RST.

The signal lines SL and the power lines PL extend over the pixel circuits PC1, PC2 and PC3 and dummy pixel circuits DPC1, DPC2 and DPC3 constituting the circuit line Ry. From another viewpoint, the pixel circuits PC1 and dummy pixel circuit DPC1 constituting the circuit line Ry are arranged along one signal line SL and one power line PL. The pixel circuits PC2 and dummy pixel circuit DPC2 constituting the circuit line Ry are arranged along one signal line SL and one power line PL. The pixel circuits PC3 and dummy pixel circuit DPC3 constituting the circuit line Ry are arranged along one signal line SL and one power line PL.

In the example of FIG. 10, a dummy pixel circuit DPC1 is located at an end of each circuit line Rx. At the opposite end of each circuit line Rx, for example, a dummy pixel circuit DPC3 is located.

In the example of FIG. 10, the dummy pixel circuits DPC1, DPC2 and DPC3 are located at an end of the circuit line Ry. A similar configuration can be applied to the opposite end of the circuit line Ry.

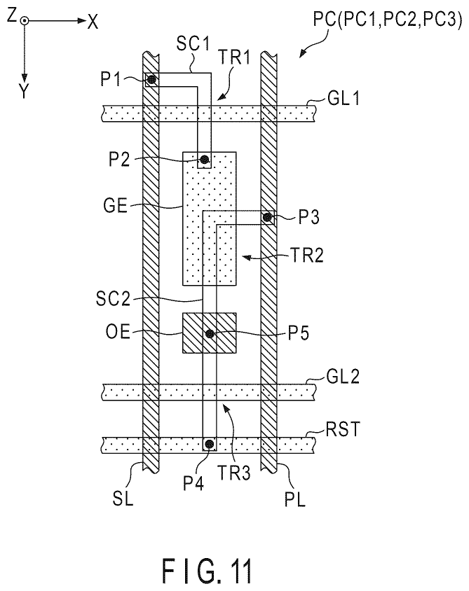

FIG. 11 is an enlarged plan view of the pixel circuit PC (PC1, CP2 or PC3) shown in FIG. 10. In the example of FIG. 11, the pixel circuit PC comprises semiconductor layers SC1 and SC2, a gate electrode GE and an output electrode OE. All of these elements are included in the circuit layer 11 shown in FIG. 5. For example, the output electrode OE is formed by the same first metal layer as the signal line SL and the power line PL. The gate electrode GE is formed by the same second metal layer as the scanning lines GL1 and GL2 and the reset line RST.

The semiconductor layer SC1 is connected to the signal line SL in a contact portion P1, and is connected to the gate electrode GE in a contact portion P2. The semiconductor layer SC1 intersects with the scanning line GL1 between the contact portions P1 and P2. This configuration constitutes the thin-film transistor TR1 shown in FIG. 2.

The semiconductor layer SC2 is connected to the power line PL in a contact portion P3, is connected to the reset line RST in a contact portion P4, and is connected to the output electrode OE in a contact portion P5. The contact portion P5 is located between the contact portions P3 and P4. The output electrode OE is connected to the lower electrode (LE1, LE2 or LE3) of the subpixel SP comprising the pixel circuit PC through the contact hole (CH1, CH2 or CH3) of the organic insulating layer 12.

The semiconductor layer SC2 intersects with the gate electrode GE between the contact portions P3 and P5. This configuration constitutes the thin-film transistor TR2 shown in FIG. 2. The semiconductor layer SC2 intersects with the scanning line GL2 between the contact portions P4 and P5. This configuration constitutes the thin-film transistor TR3 shown in FIG. 2.

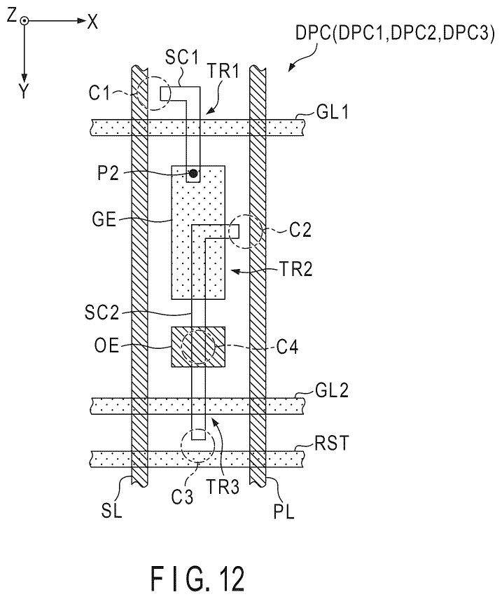

FIG. 12 is an enlarged plan view of the dummy pixel circuit DPC (DPC1, DPC2 or DPC3) shown in FIG. 10. The dummy pixel circuit DPC comprises semiconductor layers SC1 and SC2, a gate electrode GE and an output electrode OE in a manner similar to that of the pixel circuit PC. It should be noted that the circuit is disconnected in the cut portions C1, C2, C3 and C4 which are shown in FIG. 9 as well.

Specifically, the contact portion P1 shown in FIG. 11 is not provided in the cut portion C1. By this configuration, the semiconductor layer SC1 and the signal line SL are spaced apart from each other. The contact portion P3 shown in FIG. 11 is not provided in the cut portion C2. By this configuration, the semiconductor layer SC2 and the power line PL are spaced apart from each other. The contact portion P4 shown in FIG. 11 is not provided in the cut portion C3. By this configuration, the semiconductor layer SC2 and the reset line RST are spaced apart from each other. Further, the contact portion P5 shown in FIG. 11 is not provided in the cut portion C4. By this configuration, the semiconductor layer SC2 and the output electrode OE are spaced apart from each other.

It should be noted that the dummy pixel circuit DPC does not necessarily have all of the cut portions C1, C2, C3 and C4. Further, in the dummy pixel circuit DPC, the electric path between the display element DE and the dummy pixel circuit DPC may be cut in a form which is different from that of the cut portions C1, C2, C3 and C4. For example, as described above, when the contact hole (CH1, CH2 or CH3) is not provided in the dummy subpixel DSP, similarly, the electric path between the display element DE and the dummy pixel circuit DPC can be cut.

As explained above, the display device DSP of the embodiment comprises dummy pixels DPX on the external side of the pixels PX of the outermost circumference of the display area DA. This configuration can realize the improvement of the yield of the display device DSP or the improvement of reliability compared to a case where the dummy pixels DPX are not provided.

Specifically, in the configuration which does not comprise the dummy pixels DPX, there is a possibility that the thin-film transistors of the pixel circuits PC of the outermost circumference of the display area DA are destroyed by static electricity, thereby causing abnormal characteristics. In this case, such a pixel circuit PC may not function normally, and thus, the subpixel SP connected to the pixel circuit PC may be always turned off or always turned on as a defect.

To the contrary, in the display device DSP of the embodiment, the dummy pixel circuits DPC (DPC1, DPC2 and DCP3) are provided on the external side of the pixel circuits PC of the outermost circumference. In this case, even if the above destruction occurs because of static electricity, mainly, the dummy pixel circuits DPC are subjected to the damage of the destruction. Thus, the influence on the pixel circuits PC of the display area DA is reduced, and the occurrence of the above defect can be prevented.

Moreover, when the display area DA has a round portion, the destruction by static electricity easily occurs in the round portion. Therefore, when the display area DA is circular as in the case of the embodiment, the effect obtained by providing the dummy pixels DPX is further noticeable.

All of the display devices and manufacturing methods that can be implemented by a person of ordinary skill in the art through arbitrary design changes to the display device described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from the embodiments and are self-explanatory from the descriptions of the specification or can be arbitrarily conceived by a person of ordinary skill in the art are considered as the effects of the present invention as a matter of course.

What is claimed is:

1. A display device comprising:
a line which supplies a signal or voltage;
a plurality of subpixels each of which includes:
a display element including an organic layer which emits light based on application of voltage; and
a pixel circuit which drives the display element; and
a dummy subpixel which includes the display element and a dummy pixel circuit, wherein
the pixel circuits of the subpixels and the dummy pixel circuit constitute a circuit line arranged along the line,
the dummy pixel circuit is located at an end of the circuit line,
in each of the subpixels, an electric path which reaches the display element from the line through the pixel circuit is formed, and
in the dummy subpixel, at least part of an electric path which reaches the display element from the line through the dummy pixel circuit is cut.

2. The display device of claim 1, wherein
in the dummy subpixel, an electric path between the dummy pixel circuit and the display element is cut.

3. The display device of claim 1, wherein
in the dummy subpixel, an electric path between the dummy pixel circuit and the line is cut.

4. The display device of claim 3, wherein
the line includes a signal line which supplies video signals of the subpixels, and
in the dummy subpixel, an electric path between the dummy pixel circuit and the signal line is cut.

5. The display device of claim 3, wherein
the line includes a power line to which drive voltage applied to the display element of each of the subpixels is applied, and
in the dummy subpixel, an electric path between the dummy pixel circuit and the power line is cut.

6. The display device of claim 3, wherein
the line includes a reset line which applies reset voltage to the display element of each of the subpixels, and
in the dummy subpixel, an electric path between the dummy pixel circuit and the reset line is cut.

7. The display device of claim 1, wherein
the subpixels are provided in a display area which displays an image, and
an outer shape of the display area includes a nonlinear round portion.

8. The display device of claim 7, wherein
the outer shape of the display area is a circle.

9. A display device comprising:
a line which supplies a signal or voltage,
a plurality of subpixels each of which includes:
a display element including an organic layer which emits light based on application of voltage; and
a pixel circuit which drives the display element;
a dummy subpixel which includes the display element and a dummy pixel circuit; and
a partition which surrounds the display element of each of the subpixels, wherein
the pixel circuits of the subpixels and the dummy pixel circuit constitute a circuit line arranged along the line,
the dummy pixel circuit is located at an end of the circuit line,
in each of the subpixels, an electric path which reaches the display element from the line through the pixel circuit is formed, and
in the dummy subpixel, at least part of an electric path which reaches the display element from the line through the dummy pixel circuit is cut.

10. The display device of claim 9, wherein
the partition further surrounds the display element of the dummy subpixel.

11. The display device of claim 9, wherein
the partition includes:
a conductive lower portion; and
an upper portion provided on the lower portion and having an end portion which protrudes from a side surface of the lower portion.

12. The display device of claim 11, wherein
the lower portion includes:
a conductive bottom layer; and
a stem layer provided on the bottom layer, and
the bottom layer protrudes from a side surface of the stem layer.

13. The display device of claim 11, wherein
the display element of each of the subpixels includes:
a lower electrode connected to the pixel circuit;
an upper electrode which faces the lower electrode and is in contact with the lower portion of the partition, and
the organic layer located between the lower electrode and the upper electrode.

14. The display device of claim 9, wherein
in the dummy subpixel, an electric path between the dummy pixel circuit and the display element is cut.

15. The display device of claim 9, wherein
in the dummy subpixel, an electric path between the dummy pixel circuit and the line is cut.

16. The display device of claim 15, wherein
the line includes a signal line which supplies video signals of the subpixels, and
in the dummy subpixel, an electric path between the dummy pixel circuit and the signal line is cut.

17. The display device of claim 15, wherein
the line includes a power line to which drive voltage applied to the display element of each of the subpixels is applied, and
in the dummy subpixel, an electric path between the dummy pixel circuit and the power line is cut.

18. The display device of claim 15, wherein
the line includes a reset line which applies reset voltage to the display element of each of the subpixels, and
in the dummy subpixel, an electric path between the dummy pixel circuit and the reset line is cut.

19. The display device of claim 9, wherein
the subpixels are provided in a display area which displays an image, and
an outer shape of the display area includes a nonlinear round portion.

20. The display device of claim 19, wherein
the outer shape of the display area is a circle.
